(19) United States
(12) Patent Application Publication
(10) Pub. No.: US 2026/0169080 A1
(43) Pub. Date: Jun. 18, 2026

(54) SYSTEMS AND METHODS FOR ENERGY STORAGE DEVICE DIAGNOSTICS IN VEHICLES

(71) Applicant: Ford Global Technologies, LLC, Dearborn, MI (US)

(72) Inventors: Gabriel Jim, Canton, MI (US); Jason Baker, Westland, MI (US); David Lew, Canton, MI (US); Kurt Kilian, Dexter, MI (US); Parker Raus, Walled Lake, MI (US); Paul Linden, Jensen Beach, FL (US)

(73) Assignee: Ford Global Technologies, LLC, Dearborn, MI (US)

(21) Appl. No.: 18/980,023

(22) Filed: Dec. 13, 2024

(51) Int. Cl. G01R 31/3835; G01R 31/392; G01R 31/64

(52) U.S. Cl. CPC G01R 31/3835; G01R 31/392; G01R 31/64

(57) ABSTRACT

Systems and methods for diagnostics of the energy storage device of a vehicle, when the engine is running, are provided. When the engine is running, the vehicle may monitor a first voltage signal at the positive terminal of the energy storage device, a field duty cycle of a voltage generator of the vehicle, and a second voltage signal at a different or additional electronic control unit of the vehicle. If all of these signals exhibit a high ripple or low signal-to-noise ratios, it may indicate that the energy storage device has a low state of charge or poor state of health. This can be due to either the energy storage being unable to hold any charge or its charge holding capacity being severely degraded.

### FIELD

The present disclosure relates to the field of vehicle diagnostics. Specifically, embodiments of the present disclosure relate to systems and methods related to determining an underlying state of charge of an energy storage device of a vehicle when the vehicle engine is running or on.

### BACKGROUND

Most modern vehicles have a power source/energy storage device that serves several functions. For instance, most internal combustion engine (ICE) vehicles have a 12V battery that helps with starting the engine, provides power to various electrical components of the vehicle once the engine is running, and also works in conjunction with an alternator to ensure a stable supply of electrical power to the vehicle's systems. The battery also helps to stabilize voltage levels for the vehicle's electronics, preventing voltage spikes or drops. In a hybrid vehicle, a 48V battery/bank of capacitors may serve a similar purpose.

One of the traditional ways of measuring the health of the vehicle battery is the use of a battery management system (BMS) sensor. The BMS sensor monitors various parameters of the battery and communicates with the vehicle's onboard systems to protect the battery and optimize its performance. The BMS sensor monitors the overall health of the battery by analyzing parameters like capacity, voltage, and temperature over time.

### BRIEF DESCRIPTION OF THE DRAWINGS

The detailed description is set forth with reference to the accompanying drawings. The use of the same reference numerals may indicate similar or identical items. Various embodiments may utilize elements and/or components other than those illustrated in the drawings, and some elements and/or components may not be present in various embodiments. Elements and/or components in the figures are not necessarily drawn to scale. Throughout this disclosure, depending on the context, singular and plural terminology may be used interchangeably.

FIG. 1 illustrates an environment in which embodiments of the present disclosure can be implemented.

FIG. 2 illustrates a block diagram of a vehicle according to an embodiment of the present disclosure.

FIG. 3 illustrates a functional block diagram of a hybrid vehicle in which embodiments of the present disclosure can be implemented.

FIG. 4 illustrates a functional block diagram of an internal combustion engine (ICE) based vehicle in which embodiments of the present disclosure may be implemented.

FIG. 5 illustrates a schematic of an electrical system according to another embodiment of the present disclosure.

FIG. 6 illustrates a schematic of an electrical circuit that can be implemented in a vehicle according to yet another embodiment of the present disclosure.

FIG. 7 illustrates a graph showing various voltage signals measured when the underlying energy storage device is in different stages of state of charge (SOC) according to an embodiment of the present disclosure.

FIG. 8 illustrates a flow chart of a process for determining the underlying SOC of an energy storage device when the engine of a vehicle is running according to an embodiment of the present disclosure.

FIG. 9 is a flow chart for a process for determining the state of an energy storage device of a vehicle according to yet an embodiment of the present disclosure.

FIG. 10 illustrates a flow chart of a process for determining the SOH or SOC of an energy storage device of a vehicle when the engine of the vehicle is running, according to yet another embodiment of the present disclosure.

FIG. 11 illustrates a flow chart for a process of operating a vehicle according to yet another embodiment of the present disclosure.

FIG. 12 illustrates a block diagram of a server according to an embodiment of the present disclosure.

### DETAILED DESCRIPTION

### Overview

The present disclosure describes systems and methods for determining a true state of charge or a state of health of an energy storage device of a vehicle when the engine of the vehicle is running.

Embodiments of the present disclosure provide a method for determining a state of charge of an energy storage device of a vehicle. The method includes determining that an engine of the vehicle is running and measuring a duty cycle signal associated with a voltage generator of the vehicle, measuring a first voltage signal at a positive terminal of an energy storage device of the vehicle, and measuring a second voltage signal at an electronic control unit of the vehicle, the electronic control unit associated with a vehicle load. Thereafter, the method includes determining that the first duty cycle signal is noisy, determining a first signal-to-noise ratio associated with the first voltage signal, and determining a second signal-to-noise ratio associated with the second voltage signal. The method further includes determining that each of the first and the second signal-to-noise ratios are lower than a threshold and determining, based on the first duty cycle signal being noisy and the first and the second signal-to-noise ratios being lower than the threshold, that the energy storage device is malfunctioning.

In another instance, a vehicle is provided that includes an engine, a voltage generator unit coupled to the engine, an energy storage device coupled to the voltage generator unit, a first electronic control unit (ECU) coupled to the energy storage device, a second ECU coupled to a vehicle load, and a memory unit storing instructions. The vehicle is further operable to determine that the engine is running, measure a field duty cycle signal of the voltage generator unit, measure, using the first ECU, a first voltage signal at a positive terminal of the energy storage device, and measure, using the second ECU, a third voltage signal at the input of the vehicle load. The vehicle may further determine that the first voltage signal and the second voltage signal include ripples, determine that the field duty cycle signal is noisy or includes ripples, and determine, based on the first voltage and the second voltage including ripples and field duty cycle signal being noisy, that the energy storage device is defective.

In yet another instance, a method is provided that includes measuring a first voltage signal associated with a first electronic control unit (ECU) of a vehicle, measuring, using battery management system sensor, a second voltage signal associated with an energy storage device of the vehicle, and measuring a third voltage signal associated with a second ECU of the vehicle, the second ECU being different from the first ECU. The method further includes determining that each of the first voltage signal, the second voltage signal, and the third voltage signal has a respective signal-to-noise ratio that is lower than a threshold and determining, based on the respective SNR of the first voltage signal, the second voltage signal, and the third voltage signal being lower than the threshold, that the energy storage device is defective.

These and other advantages of the present disclosure are provided in detail herein.

### Illustrative Embodiments

The disclosure will be described more fully hereinafter with reference to the accompanying drawings, in which example embodiments of the disclosure are shown, and not intended to be limiting.

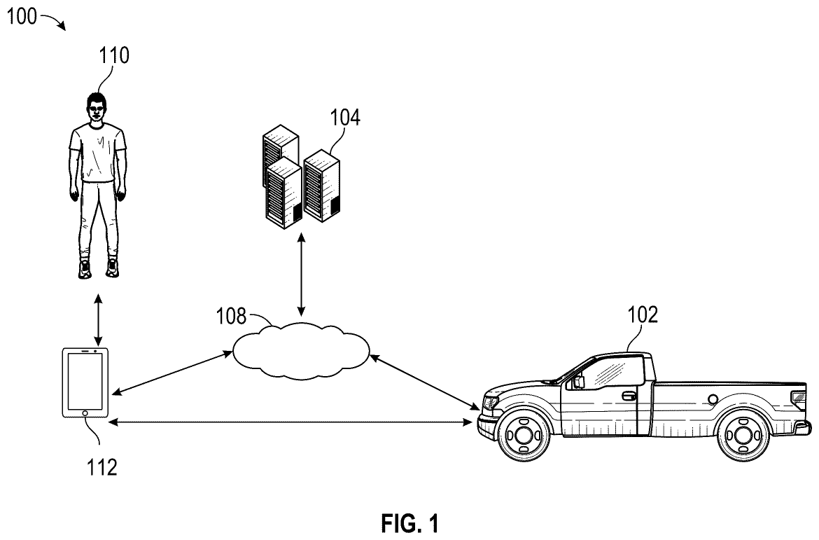

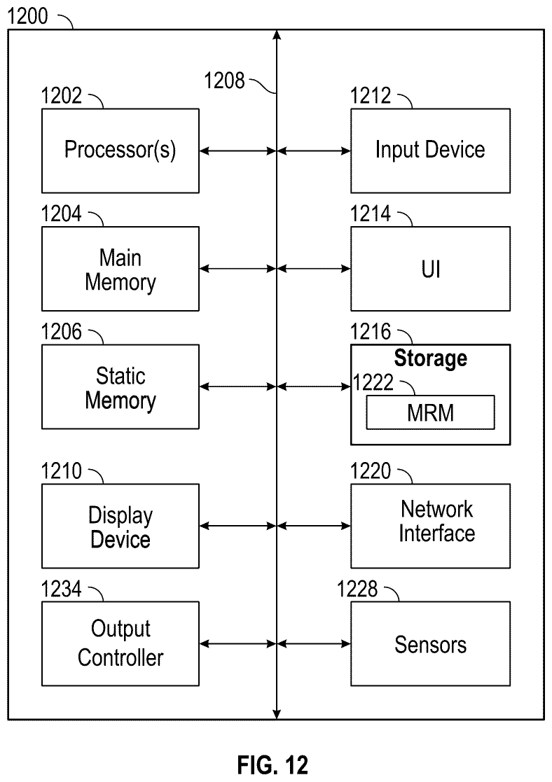

FIG. 1 illustrates an environment 100 in which the embodiments of the present disclosure may be implemented. The vehicle 102 can be any passenger or commercial vehicle such as a car, truck, tanker, bus, or the like. The environment 100 may also include a control server 104. The control server 104 may be part of a cloud-based computing infrastructure and may be associated with and/or include a Telematics Service Delivery Network (SDN) that provides digital data services to the vehicle 102. Details of the control server 104 are provided below with reference to FIG. 12.

The environment 100 may also include a user device 112. The user device 112 may be one of a mobile phone, a tablet, a personal computer, a smart key fob, or the like. The user device 112 may be associated with a user 110 of the vehicle 102. The user 110 may be a driver of the vehicle 102 or a passenger in the vehicle 102. The user device 112 may receive information from the vehicle 102 and/or the control server 104. The user device 112 may have a specialized application installed on it that can interface with the vehicle 102 to download and display various types of vehicle-generated information and other control data. In one embodiment, the vehicle 102 may directly communicate with the user device 112 to send and receive data without the need for the network 108 and/or the server 104.

The environment 100 may further include a network 108. The network 108 illustrates an example communication infrastructure in which the connected devices discussed in various embodiments of this disclosure may communicate. The network 108 may be and/or include the Internet, a private network, public network, or other configuration that operates using any one or more known communication protocols such as, for example, transmission control protocol/Internet protocol (TCP/IP), Bluetooth®, Bluetooth® Low Energy (BLE), Wi-Fi based on the Institute of Electrical and Electronics Engineers (IEEE) standard 802.11, Ultra-Wideband (UWB), and cellular technologies such as Time Division Multiple Access (TDMA), Code Division Multiple Access (CDMA), High-Speed Packet Access (HSPDA), Long-Term Evolution (LTE), Global System for Mobile Communications (GSM), and Fifth Generation (5G), to name a few examples.

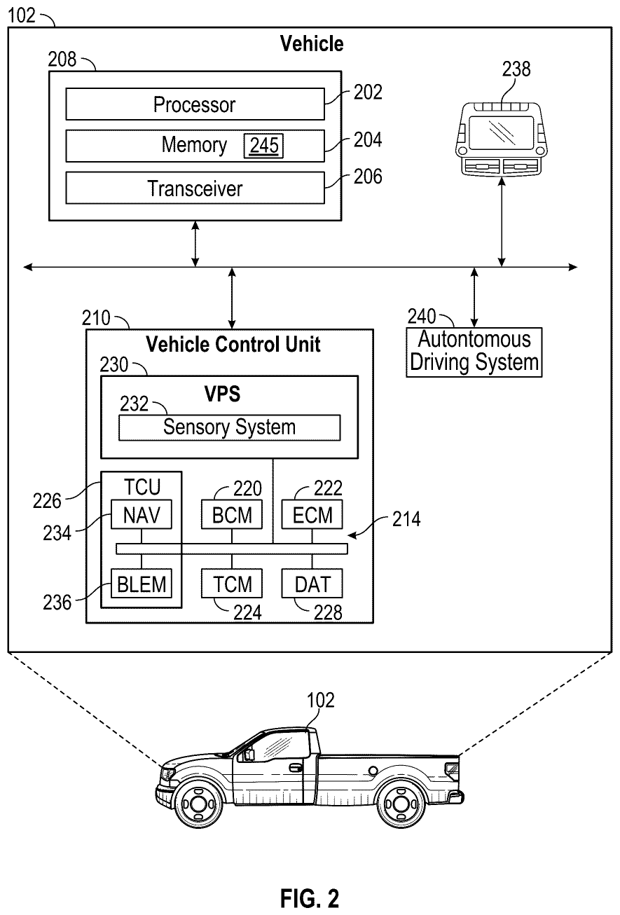

The vehicle 102 may include a plurality of units including, but not limited to, an automotive computer, a Vehicle Control Unit (VCU), and a detection unit. Details of the vehicle 102 are provided below in reference to FIG. 2.

FIG. 2 illustrates a block diagram of the vehicle 102 in which embodiments of the present disclosure can be implemented. The vehicle 102 may include a plurality of units including, but not limited to, an automotive computer 208, a Vehicle Control Unit (VCU) 210, and an infotainment unit 238. The VCU 210 may include a plurality of Electronic Control Units (ECUs) 214 in communication with the automotive computer 208.

In some embodiments, a user device, such as a mobile phone, a laptop computer, a smart fob, or the like, may be configured to connect with the automotive computer 208, which may communicate via one or more wireless connection(s), and/or may connect with the vehicle 102 directly by using near field communication (NFC) protocols, Bluetooth®protocols, Wi-Fi, Ultra-Wideband (UWB), and other possible data connection and sharing techniques.

The automotive computer 208 may be installed anywhere in the vehicle 102, in accordance with the disclosure. The automotive computer 208 may be or include an electronic vehicle controller, having one or more processor(s) 202, one or more memory devices 204, and one or more transceivers 206.

The processor(s) 202 may be disposed in communication with one or more memory devices disposed in communication with the respective computing systems (e.g., the memory 204 and/or one or more external databases not shown in FIG. 2). The processor(s) 202 may utilize the memory 204 to store programs in code and/or to store data for performing operations in accordance with the disclosure. The memory 204 may be a non-transitory computer-readable storage medium or memory storing a vehicle control program code. The memory 204 may include any one or a combination of volatile memory elements (e.g., dynamic random-access memory (DRAM), synchronous dynamic random-access memory (SDRAM), etc.) and may include any one or more nonvolatile memory elements (e.g., erasable programmable read-only memory (EPROM), flash memory, electronically erasable programmable read-only memory (EEPROM), programmable read-only memory (PROM), etc.). In some embodiments, memory 204 may include a module 245 that can implement the various embodiments of the present disclosure. Module 245 may include instructions that can be executed by the processor 202 to realize the various embodiments of the present disclosure.

Automotive computer 208 may also include a transceiver 206. The transceiver 206 may be configured to receive information/inputs from one or more external devices or systems, e.g., a user device 208, an external server, and/or the like. Further, the transceiver 206 may transmit notifications, requests, signals, etc., to the external devices or systems. In addition, the transceiver 206 may be configured to receive information/inputs from vehicle components such as the vehicle sensory system 232, one or more ECUs 214, and/or the like. Further, the transceiver 206 may transmit signals (e.g., command signals) or notifications to the vehicle components such as the BCM 220, the infotainment system 238, and/or the like.

In some embodiments, the VCU 210 may share a power and/or communications bus with the automotive computer 208 and may be configured and/or programmed to coordinate the data between vehicle systems, connected servers, and/or the like. The VCU 210 may include or communicate with any combination of the ECUs 214, such as, for example, the BCM 220, an Engine Control Module (ECM) 222, a Transmission Control Module (TCM) 224, a Telematics Control Unit (TCU) 226, a Driver Assistance Technologies (DAT) controller 228, etc. The VCU 210 may further include and/or communicate with a Vehicle Perception System (VPS) 230, having connectivity with and/or control of one or more vehicle sensory system(s) 232. The vehicle sensory system 232 may include one or more vehicle sensors including, but not limited to, a Radio Detection and Ranging (RADAR or “radar”) sensor configured for detection and localization of objects inside and outside the vehicle 102 using radio waves, sitting area buckle sensors, sitting area sensors, a Light Detecting and Ranging (“LIDAR”) sensor, door sensors, proximity sensors, temperature sensors, wheel sensors, one or more ambient weather or temperature sensors, vehicle interior and exterior cameras, steering wheel sensors, etc. The sensors that are part of the vehicle sensory system 232 may be coupled to the vehicle 102 at one or more locations and in one or more manner. For example, the various sensors of the vehicle sensory system 232 may be integrated into the various subsystems of the vehicle 102, such as doors, mirrors, roof, etc., or attached to the vehicle 102 using an appropriate mounting mechanism. In some embodiments, the various sensors of the vehicle sensory system 232 may be located at the front, back, sides, top, bottom, and underneath the vehicle 102. The location of a sensor may depend on its function. For example, a sensor that monitors the area underneath the vehicle may be connected to the bottom surface of the vehicle 102 while a sensor that can monitor an area to any side of the vehicle 102 may be mounted or integrated into the doors of the vehicle 102. Vehicle sensory system 232 may also include one or more road noise sensors such as accelerometers that are coupled to various mechanical components and/or systems of the vehicle 102. One skilled in the art will realize that the sensors may be coupled to the vehicles in various different ways and locations other than the ones mentioned above.

In some embodiments, the VCU 210 may control vehicle operational aspects and implement one or more instruction sets received from the server 104, the user device 112, or from one or more instruction sets stored in the memory 204.

The TCU 226 may be configured and/or programmed to provide vehicle connectivity to wireless computing systems onboard and off board the vehicle 102, and may include a Navigation (NAV) receiver 234 for receiving and processing a GPS signal, a BLE® Module (BLEM) 236, a Wi-Fi transceiver, a UWB transceiver, and/or other wireless transceivers (not shown in FIG. 2) that may be configurable for wireless communication (including cellular communication) between the vehicle 102 and other systems (e.g., a vehicle key fob (not shown in FIG. 2), an external server, a user device, etc.), computers, and modules. The TCU 226 may be in communication with the ECUs 214 by way of a wired or wireless bus. In some aspects, the TCU 226 may be configured to determine a real-time vehicle geolocation, e.g., via the NAV receiver 234.

The ECUs 214 may control aspects of vehicle operation and communication using inputs from human drivers, inputs from the automotive computer 208, and/or via wireless signal inputs received via the wireless connection(s) from other connected devices, such as the server 206, among others.

The BCM 220 generally includes integration of sensors, vehicle performance indicators, and variable reactors associated with vehicle systems and may include processor-based power distribution circuitry that may control functions associated with the vehicle body such as lights, windows, security, camera(s), audio system(s), speakers, wipers, door locks and access control, various comfort controls, etc. The BCM 220 may also operate as a gateway for bus and network interfaces to interact with remote ECUs (not shown in FIG. 2).

The DAT controller 228 and/or the autonomous driving system 240 may provide Level-1 through Level-5 automated driving and driver assistance functionality that may include, for example, active parking assistance, vehicle backup assistance, and/or adaptive cruise control, among other features. The DAT controller 228 may also provide aspects of user and environmental inputs that are usable for user authentication.

In some embodiments, the automotive computer 208 may connect with an infotainment system 238 (or a vehicle Human-Machine Interface (HMI)). The infotainment system 238 may include a touchscreen interface portion and may include voice recognition features, biometric identification capabilities that may identify users based on facial recognition, voice recognition, fingerprint identification, or other biological identification means. In other aspects, the infotainment system 238 may be further configured to receive user instructions via the touchscreen interface portion and/or output or display notifications, navigation maps, etc., on the touchscreen interface portion. In some embodiments, the user device 112 may provide the HMI interface.

The computing system architecture of the automotive computer 208 and/or the VCU 210 may omit certain computing modules. It should be readily understood that the computing environment depicted in FIG. 2 is an example of a possible implementation according to the present disclosure, and thus, it should not be considered as limiting or exclusive.

In addition to the components noted above, the vehicle 102 may have numerous mechanical systems and sub-systems. A chassis or frame may form the backbone of the vehicle 102 and support the body and other components of the vehicle 102. The vehicle 102 may include an engine that converts fuel into mechanical power, propelling the vehicle forward. The engine includes various components such as the engine block, pistons, valves, and spark plugs. The vehicle 102 may also include a transmission system. The transmission system transfers the engine's power to the wheels. It includes the clutch, gearbox, driveshaft, and differentials, among other components. The transmission adjusts the power output to suit the vehicle's speed and load. The vehicle 102 may also include a suspension system. The suspension system absorbs shocks and maintains contact between the tires and the road, providing a smooth ride. It includes components such as springs, shock absorbers, and linkages. The vehicle 102 also includes a vehicle-stopping system that allows the driver to slow down or stop the vehicle 102. It includes components like pedals, master cylinders, lines, and pads or shoes. The vehicle 102 also includes a steering system that enables the driver to guide the car. The steering system includes components such as the steering wheel, steering column, rack and pinion, and tie rods. The vehicle 102 may also include an exhaust system that removes and filters the waste gases produced by the engine. It includes the exhaust manifold, catalytic converter, muffler, and tailpipe, among other components. The vehicle 102 also includes a cooling system that prevents the engine and/or battery from overheating. It includes components such as the radiator, water pump, thermostat, and coolant. The vehicle 102 also includes a cooling system that stores and supplies fuel to the engine. It includes the fuel tank, fuel pump, fuel filter, and fuel injectors. An electrical system of the vehicle 102 powers the car's electrical components. It may include the battery, alternator, starter motor, and wiring. The Heating, Ventilation, and Air Conditioning (HVAC) system controls the temperature inside the vehicle 102. It includes the heater core, blower motor, and air conditioning compressor. In some embodiments, the vehicle may be an electric vehicle (EV) or hybrid vehicle, and in either case, some of the aforementioned components would be replaced by an electric motor and a high-voltage battery. All of the mechanical components working together ensure that the vehicle 102 operates optimally.

Most ICE vehicles, hybrid vehicles, and electric vehicles (EVs) have some sort of a power source/energy storage device, such as a battery or a capacitor, that provides electrical power to one or more components of the vehicle's electrical system. This energy storage device also helps to start the engine (e.g., in ICE and hybrid vehicles) and works in conjunction with an alternator or a belt-integrated starter generator (BISG) to provide a stable supply to electrical power to the various systems of the vehicle. Thus, it is beneficial to monitor the health of this energy storage device to ensure optimal operation of the energy storage device and the vehicle.

If the energy storage device is a battery, one of the most common ways of monitoring the health of the battery is to monitor its state of health (SOH). SOH refers to the overall health or condition of the battery, measuring how much of its original capacity it has retained compared to when it was new. In other words, a battery SOH indicates the battery's ability to store and deliver energy over time. It indicates the battery's remaining useful life and its ability to maintain performance. Another parameter commonly used to monitor the function of a battery is a state of charge (SOC) parameter. The SOC refers to the amount of charge currently stored in the battery relative to its total capacity. It is often expressed as a percentage, from 0% (empty) to 100% (fully charged). In other instances, the SOC is measured as a voltage or ampere-hour (Ah) value that reflects the amount of charge relative to the total capacity. A common way to measure this SOC is using a BMS sensor. The BMS sensor measures a voltage across the battery terminals. For example, if the battery is rated as a 12V battery, then any voltage that is less than 12V may be considered a low voltage and may indicate an issue with the battery (e.g., the battery being defective or malfunctioning). Voltages in the range of 12.4V to 12.8V indicate a healthy battery. A battery with a low voltage may not be able to start the engine and/or provide enough power to the various components of the vehicle.

It is relatively easy to determine the SOC of a battery when the engine is off, as there is no other power input into the battery. So, if the SOC of the battery is low while the engine is off, it usually manifests itself in the battery's inability to start the engine. In such instances, the user of the vehicle may be notified of the issue with the battery via the HMI system of the vehicle or via a user device. However, when the engine is running, the alternator (or BISG in case of hybrid vehicles) generates alternating current (AC) by converting the mechanical energy from the engine to electrical energy. The alternating current is converted to direct current (DC) by a rectifier and provided to a voltage regulator. The voltage regulator controls the amount of power provided to the battery. Usually, the voltage regulator provides between 13.7V to 14.7V to the battery when the engine is running. Thus, when the engine is running, it is hard to estimate the actual battery SOH or SOC since the output measured at the battery terminals will always indicate that the battery is fully or adequately charged. Therefore, even if the underlying SOC of the battery is low, it will not be evident when the engine is running. In such instances, once the engine is turned off the SOC of the battery will likely fall below the optimal value, and the battery will be unable to start the engine rendering the vehicle inoperable.

Embodiments of the present disclosure mitigate this issue by providing systems and methods to determine the actual SOC of a battery when the engine is running, thus alerting the user of a potential battery issue while the engine is still on, so that user may take the appropriate action, such as taking the car to a mechanic to get the battery inspected and/or replaced. In other words, embodiments of the present disclosure provide systems and methods to accurately determine the underlying/actual SOC and/or SOH of the battery even when the actual SOC of the battery is masked due to engine running and the alternator providing voltage to the battery.

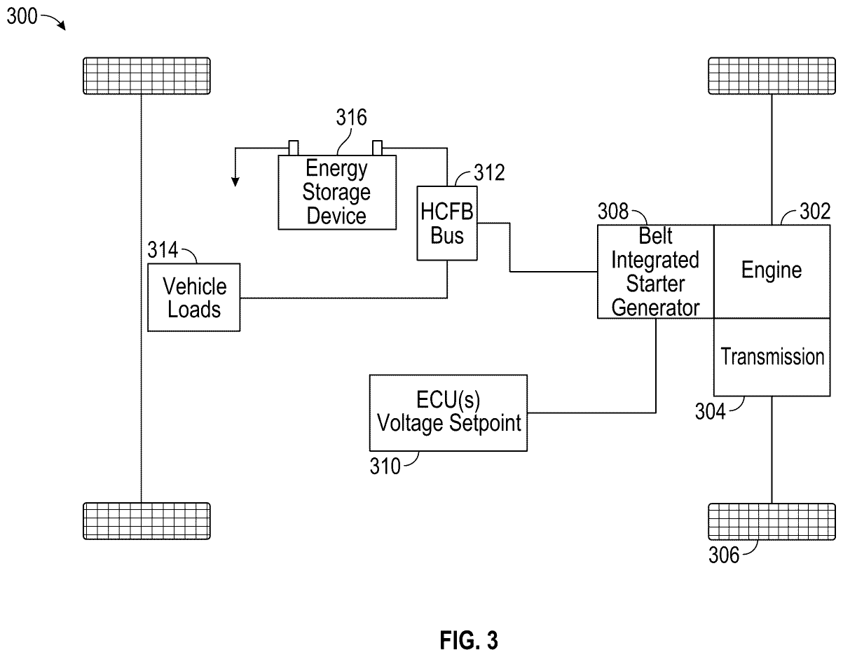

FIG. 3 illustrates a functional block diagram of a hybrid vehicle 300 in which embodiments of the present disclosure can be implemented. The vehicle 300 may be implemented using the vehicle 102 of FIG. 2. The vehicle may include an engine 302 coupled with a transmission unit 304. In some instances, the vehicle 300 may include more than one engine 302. A plurality of wheels 306 are coupled to the transmission unit 304. A belt-integrated starter generator (BISG) 308 may be coupled to the engine. The BISG 308 serves as a starter motor for the engine 302 and performs various other functions that are well-known in the art. A vehicle electronic control unit (ECU) 310 provides a voltage setpoint value to the BISG 308. The specific voltage level required for the BISG 308 to operate is determined by a combination of factors, such as the vehicle's operating mode, the state of charge of the high-voltage battery, and the demands on the powertrain at any given moment. The BISG may be communicably coupled with an energy storage device 316 via a communication bus 312. In an embodiment, the energy storage device 316 may be a single capacitor, a bank of capacitors, or a battery. In another embodiment, the communication bus 312 may be implemented as a High Voltage CAN (Controller Area Network) Flexibility Bus or High Voltage Communication Flex Bus (HCFB). The HCFB bus facilitates communication between electrical systems in the vehicle, such as the battery, electric motor, and inverters. It allows these components to exchange data on performance, state of charge, in consumption, and fault monitoring, which is used for managing the energy flow in electric and hybrid vehicles.

The communication bus 312 receives input from a vehicle load unit 314. The vehicle load unit 314 represents a combination of various vehicle loads, such as electrical loads (e.g., infotainment system, climate control, lighting, power seats, and mirrors, etc.) and mechanical loads (e.g., alternator, powertrain components, drive motors, fuel pumps, etc.). In operation, the vehicle ECU 310 provides a voltage setpoint to the BISG 308 that outputs a voltage based on the setpoint to charge the energy storage device 316. The energy storage device 316, in conjunction with the BISG 308 provides the requisite power to the various electrical systems of the vehicle 300.

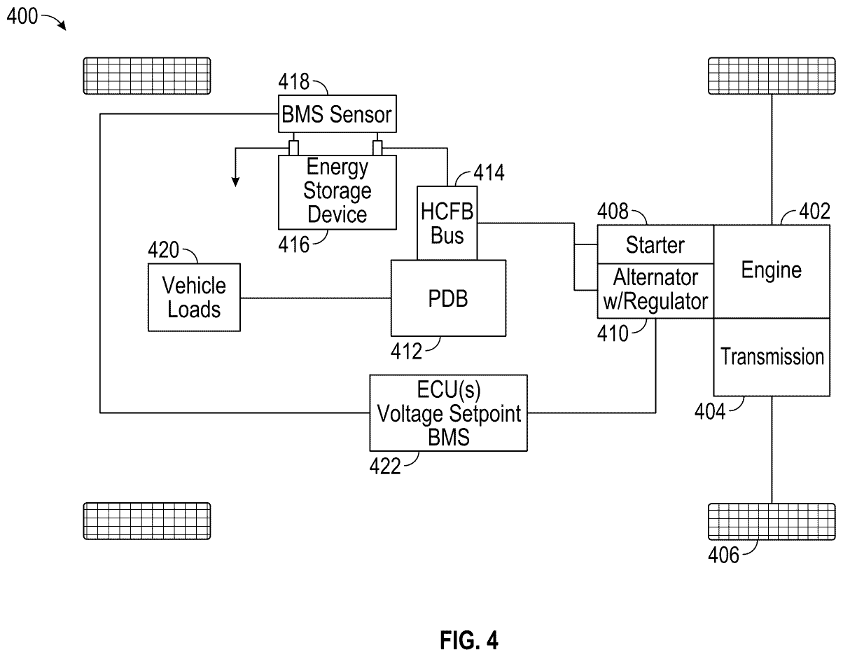

FIG. 4 is a functional block diagram of an internal combustion engine (ICE) based vehicle 400 in which embodiments of the present disclosure may be implemented. The vehicle 400 includes an ICE engine 402 coupled with a transmission unit 404. A plurality of wheels 406 are coupled to the transmission unit 404. The engine 402 is further coupled with a starter 408 and an alternator 410 that may include a voltage regulator. The functions of the starter 408 and the alternator 410 are well-known in the art and are omitted here for brevity. The starter 408 and the alternator 410 are coupled to an energy storage device 416 via a communications bus 414. One or more vehicle electrical and mechanical systems, represented by the vehicle load box 420, are coupled to the alternator 410 and the energy storage device 416 via a power distribution box (PDB) 412. In some embodiments, the energy storage device 416 may be a battery. In a specific embodiment, the energy storage device 416 may be a 12V-rated battery. A battery management system (BMS) sensor 418 may be coupled with the energy storage device 416. The function of the BMS sensor 418 is described above. The vehicle 400 may also include a BMS voltage setpoint ECU 422 that determines and provides a voltage setpoint to the alternator 410. The alternator 410 outputs an appropriate voltage in response to the setpoint received from the ECU 422. The ECU determines the setpoint based on the actual voltage measured by the BMS sensor 418. The operation of the components of vehicle 400 is well-known in the art and is not repeated here for brevity.

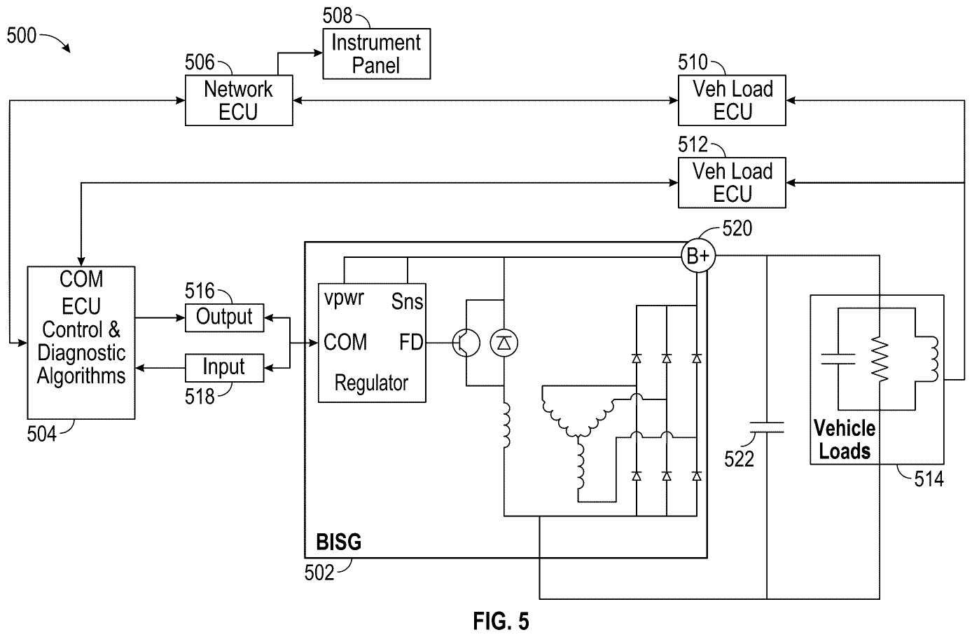

FIG. 5 illustrates a schematic of an electrical system 500 according to an embodiment of the present disclosure. The electrical system 500 can be implemented in any of the vehicles 300 or 400 described above with appropriate modifications. Specifically, the electrical system 500 can be implemented in a hybrid vehicle (e.g., the vehicle 300 illustrated in FIG. 3). The electrical system 500 includes a BISG unit 502 that is coupled with a vehicle load 514. The vehicle load 514 represents one or more electrical systems of the vehicle. However, for ease of understanding, the various vehicle loads are represented in the schematic as a single unit 514. The representative vehicle load 514 is electrically coupled with a first vehicle ECU 510, and a second vehicle ECU 512. It is to be noted that the vehicle load 514 may be electrically coupled to more than two ECUs, but FIG. 5 only illustrates two ECUs for ease of explanation and understanding. One skilled in the art will realize that a vehicle typically includes multiple ECUs (e.g., as illustrated in FIG. 2 above). The various ECUs of a vehicle may include a TCU, an ECM, a BCM, a VCU, etc. The ECU 512 and the ECU 510 may represent any of these various ECUs.

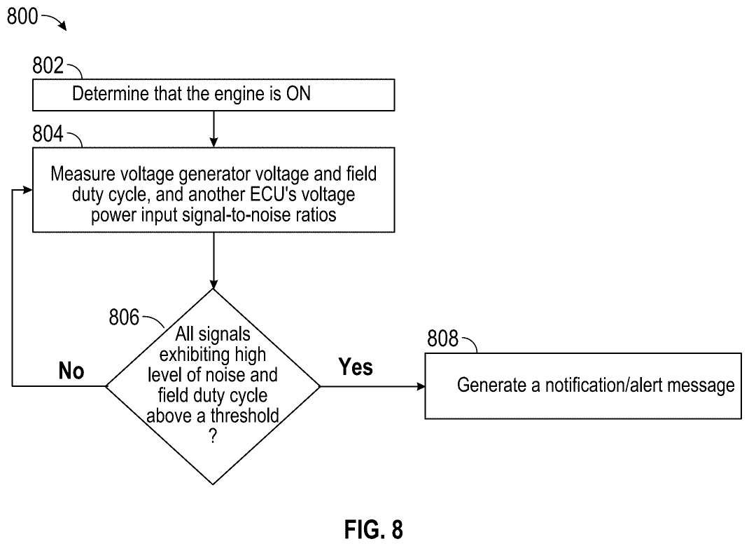

The ECU 510 may be electrically coupled with a network ECU 506. The network ECU 506 manages and facilitates communication between various ECUs across the vehicle's network. The network ECU 506 may be electrically coupled with an instrument panel 508 of the vehicle. In an embodiment, the instrument panel 508 may be part of the HMI system of the vehicle and may include a display that outputs vehicle related information in a visual form. The network ECU 506 and the second vehicle ECU 512 are both electrically coupled to a control and diagnostics module 504. The control and diagnostics module 504 includes the instructions/algorithms that are needed to implement embodiments of the present disclosure. The control and diagnostics module 504 is coupled to the BISG unit 502 via an input path 518 and an output path 516. The BISG unit 502 outputs a voltage that is used to charge an energy storage device 522. A B+ voltage 520 (e.g., the voltage on the positive terminal of a batter) may be detected at a positive terminal of the energy storage device 522. As described above, the energy storage device 522 may be a battery or a capacitor bank. The operation of the circuit 500 will now be explained in conjunction with the flow chart illustrated in FIG. 8.

FIG. 8 illustrates a flow chart of a process 800 for determining the underlying SOC of an energy storage device when the engine of a vehicle is running according to an embodiment of the present disclosure. As described above, when the engine is running or ‘on’, the BISG unit 502 may output a voltage to charge the energy storage device 522. However, if the energy storage device 522 is dead or severely discharged, it leads to voltage ripple in the output voltage of the BISG unit 502, which also the B+ voltage 520 at the positive terminal of the energy storage device 522. Voltage ripple refers to fluctuations or variations in the DC voltage that the BISG unit 502 provides to the energy storage device 522 and other electrical systems in the vehicle. These ripples in the B+ voltage 520 can be detected by the vehicle ECUs 510 and/or 512. The control and diagnostics module 504, which is electrically coupled to both the ECUs 510 and 512, can detect these voltage ripples. Thus, the process 800 includes the initial step 802 of determining that the engine is on. If the energy storage device 522 is dead or deeply discharged, the energy storage device 522 cannot stabilize the output voltage from the BISG unit 502, which leads to higher voltage ripple. The output voltage of the BISG unit 502 is typically stabilized by the energy storage device 522, which acts as a “filter” to smooth out voltage fluctuations. Without the energy storage device 522 being able to hold a charge, the ripple caused by the AC-to-DC conversion is less dampened, and this manifests as more noticeable fluctuations in the B+ voltage 520. In other words, the BISG unit 502 needs a range of impedance or capacitance Farads associated with the energy storage device 522 to provide clean regulated power. However, when the impedance is either too low (e.g., an internal short of a cell in the energy storage device), or too high (e.g., an internal open circuit, or the Capacitor's Farads is too low or not present), the BISG unit 502 output will become noisy.

Additionally, if the energy storage device 522 is dead or severely discharged, it may also affect the field duty cycle signal of the BISG unit 502. The field duty cycle refers to the amount of time the BISG unit 502 is actively engaged in its various functions (such as starting the engine, assisting the engine, or acting as a generator for energy recovery) relative to the total time in a given cycle or operating period. It is expressed as a percentage, representing how often the BISG unit 502 is in operation compared to idle time or other non-operating states. If the field duty cycle signal of the BISG is noisy and includes ripples, (i.e., the signal-to-noise ratio is below a threshold) it may be an indication that the energy storage device 522 is either dead or severely discharged. In addition to the B+ voltage 502 at the positive terminal of the energy storage device 522, other ECUs in the vehicle may also detect a high signal-to-noise ratio for the voltage signal being provided to other electrical systems in the vehicle due to the ripple caused in the output voltage of the BISG unit 502. Thus, at step 804, the process 800 measures the output voltage of the BISG unit 502/B+ voltage 520, the field duty cycle signal of the BISG, and voltage input for at least one more ECU of the vehicle. At step 806, the vehicle determines whether the B+ voltage signal and the voltage signal detected by at least one other ECU of the vehicle exhibit a low signal-to-noise ratio. In addition, at step 806, it is determined whether the SNR of the field duty cycle signal of the BISG is below a threshold. If at step 806, it is determined that B+ voltage, the field duty cycle signal, and voltage detected by the at least one other ECU in the vehicle all have a low signal-to-noise ratio, then the vehicle may infer that the energy storage device 522 is dead, severely discharged, or otherwise non-operational. Based on this determination, the vehicle may output an alert message or notification informing the vehicle occupant of the issue with the energy storage device (e.g., the energy storage device being defective or malfunctioning), at step 808. If at step 806, it is determined that not all of the measure signals show a high signal-to-noise ratio, then the energy storage device 522 likely has no issues and the process 800 returns to step 804.

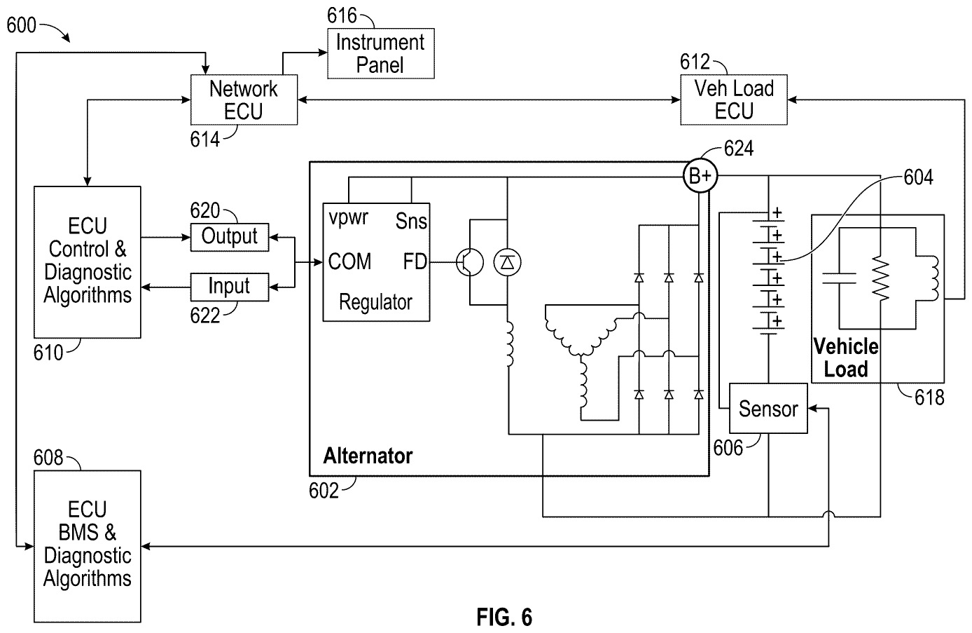

FIG. 6 illustrates a schematic of an electrical circuit 600 that can be implemented in a vehicle according to an embodiment of the present disclosure. Specifically, the electrical circuit 600 may be implemented in the vehicle 400 of FIG. 4. The circuit 600 includes an alternator 602 coupled to an energy storage device 604 and a vehicle load 618. In an embodiment, the alternator may include a voltage regulator. The vehicle load 618 may be a representation of one or more vehicle loads described above. A sensor 606 is coupled between the two terminals of the energy storage device 604. The sensor 606 measures a current voltage across the two terminals of the energy storage device 604 and reports that voltage value to energy storage diagnostic ECU 608. The energy storage diagnostics ECU 608 is electrically coupled to network ECU 614. The network ECU is coupled to an instrument panel 616. In an embodiment, the instrument panel 616 may be similar to the instrument panel 508 described above.

The network ECU 614 is also electrically coupled with a control and diagnostics ECU 610 and a vehicle load ECU 612. The vehicle load ECU 612 may be similar to the other vehicle load ECUs described above and is electrically coupled with the vehicle load 618. The control and diagnostics ECU 610 is electrically coupled with the alternator 602. In operation, the alternator 602 outputs a voltage to the energy storage device 604 and to the other vehicle loads 618. The sensor 606 continually measures the voltage across the terminals of the energy storage device 604 and reports that voltage to the energy storage diagnostics ECU 608. Based on the measured voltage by the sensor 606, the energy storage diagnostics ECU 608 provides a voltage set point value to the alternator 602 via the network ECU 614 and the control and diagnostics ECU 610. The alternator then adjusts its output voltage based on the set point. The control and diagnostics ECU 610 is coupled with the alternator via an input path 622 and an output path 620. The voltage output by the energy storage device 604 is measured as the B+ voltage 624 at the positive terminal of the energy storage device 604.

In the event that the energy storage device 604 is not functioning properly (e.g., due to an internal short, open circuit, etc.), it is not able to effectively filter the output voltage of the alternator 602. This results in the output voltage of the alternator becoming noisy. In addition, it may also cause ripples in the voltage that can be measured/detected in the B+ voltage 624 of the energy storage device 604. FIG. 10 illustrates a flow chart of a process 1000 for determining the SOH or SOC of an energy storage device of a vehicle when the engine of the vehicle is running, according to an embodiment of the present disclosure. The following description is provided with reference to both FIGS. 6 and 10. At step 1002, the vehicle may determine that the engine is on or running. At step 1004, the vehicle may measure the B+ voltage at the BCM (Body Control Module), the voltage between the two terminals of an energy storage device (e.g., the energy storage device 604), and the voltage input at one more ECU of the vehicle.

Thereafter, at step 1006, the vehicle may determine whether one or more of the measured voltage signals exhibit a signal-to-noise (SNR) ratio that is below a threshold. For example, an SNR ratio of 20 dB or lower may be considered a low SNR. If at step 1006, it is determined that one or more of the measured voltage signals do not exhibit a low SNR, the process 1000 returns to step 1004 and continues to monitor the requisite voltage signals. If at step 1006, the vehicle determines that all of the measured voltage signals exhibit a low SNR (i.e., the signals are noisy and have substantial ripple), the vehicle may infer that the energy storage device 604 has some issue or is otherwise non-operational (e.g., open circuit, internal short, low Farads, etc.). Based on the determination that the energy storage device 604 has some issues, the vehicle may output a notification or alert message indicating that the energy storage device 604 should be inspected, at step 1008. In addition, the vehicle may increase the alternator output, and/or temporarily suspend some of the fuel-saving strategies, such as engine start/stop.

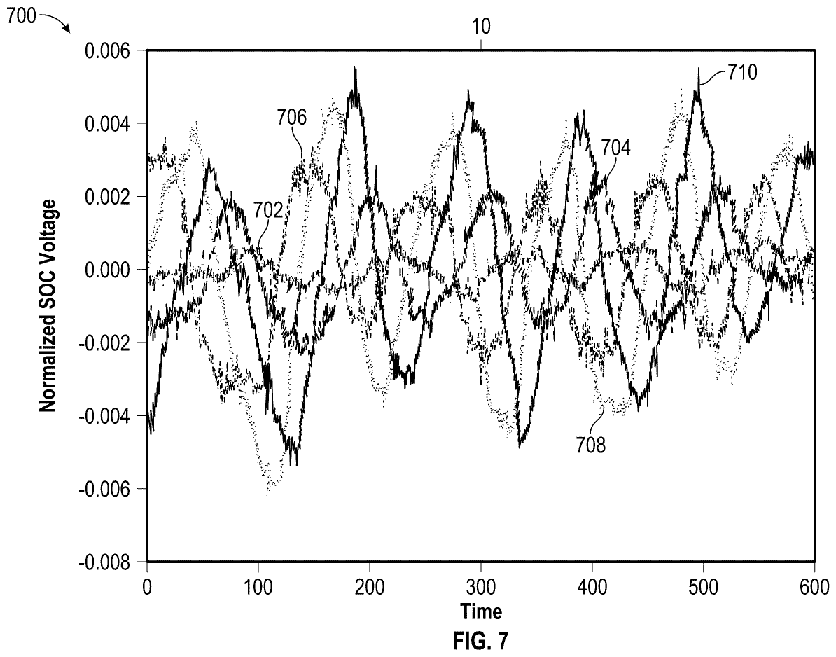

FIG. 7 illustrates a graph 700 showing various B+ (or other ECU) voltage signals measured when the underlying energy storage device is in different stages of SOC according to an embodiment of the present disclosure. As noted above, if the energy storage device is dead or cannot hold charge, the resulting B+ voltage exhibits ripples, and the alternator output is not stable. In the graph 700, the X-axis represents time, and the Y-axis represents normalized SOC signal of the energy storage device when the engine is running or on. When the engine is running and the energy storage device is functioning normally (i.e., it is healthy and can hold a full or 100% SOC), the vehicle ECU detects a signal that is similar to the signal 702. As can be seen, the signal 702 is fairly stable with very little peak-to-peak variation. Such a signal represents good underlying SOH/SOC of the energy storage device of the vehicle. The signals 704-710 represent the energy storage device in a progressively worse SOH/SOC as each of the signals 704-710 shows increasing peak-to-peak variations. For instance, the signal 710 has the highest peak-to-peak variation and may represent an energy storage device that is likely dead and is unable to hold any charge. Thus, measuring the B+ and/or the alternator voltage output can provide an indication of the SOC/SOH of the underlying energy storage device even when the engine is running. As described above, the vehicle measures and analyses signals such as the signals 702-710 as part of the processes 800 and 1000.

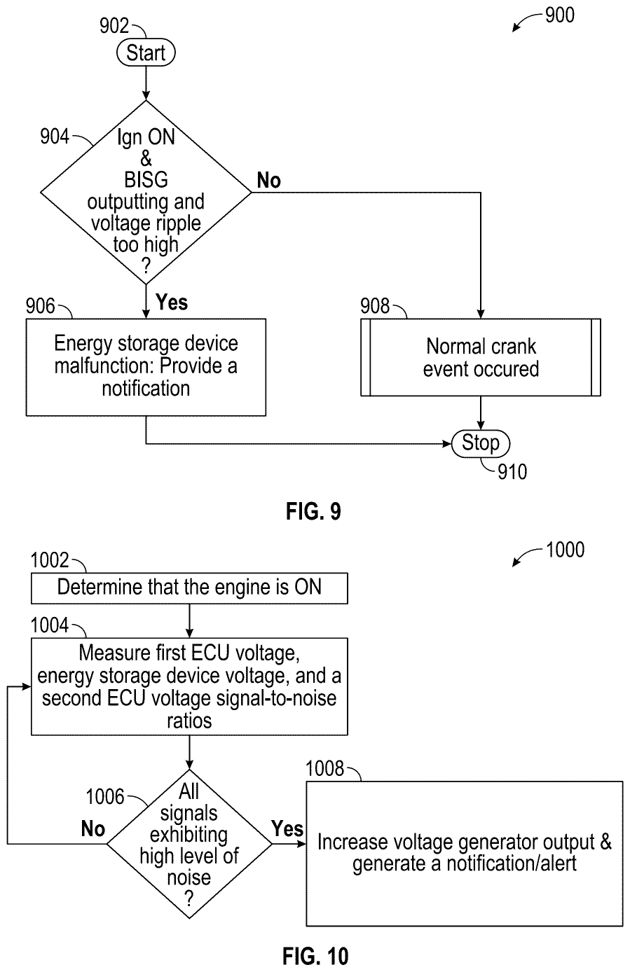

FIG. 9 is a flow chart for a process 900 according to an embodiment of the present disclosure. Process 900 can be performed by any of the vehicles 102, 300, or 400 described above. At step 902, the process 900 begins, where the vehicle starts monitoring the voltage generator output voltage, the B+ voltage at the energy storage device, and the input voltages measured by one or more other ECUs of the vehicles that are coupled to their respective vehicle loads. At step 904, the vehicle may determine that the ignition is on, and the voltage generator is outputting a voltage. The vehicle may further determine if the voltage output by the voltage generator has ripples (e.g., high peak-to-peak variations). If it is determined that the voltage has ripples or low SNR, the vehicle may conclude that the underlying energy storage device has issues and generate a notification indicating an issue with the energy storage device at step 906s. The process then terminates at step 910. If the vehicle determines at step 904 that the output voltage of the voltage generator does not have ripples, the vehicle may conclude, at step 908, that the underlying energy storage device is working optimally and that a normal engine crank event occurred. The process 900 then ends or terminates at step 910.

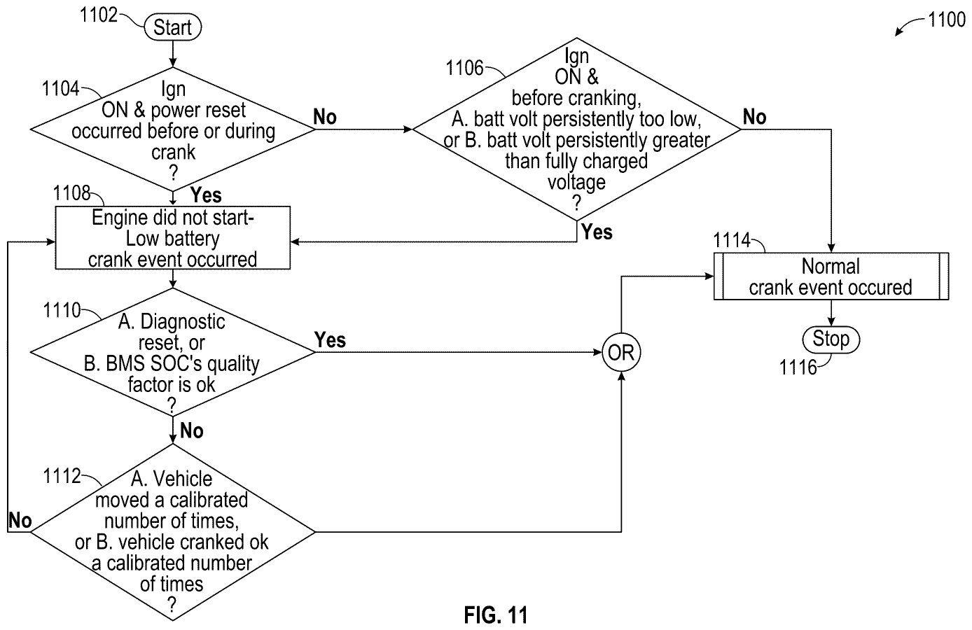

FIG. 11 illustrates a flow chart for a process 1100 according to yet another embodiment of the present disclosure. Process 1100 can be performed by any of the vehicles 102, 300, or 400 described above. Process 1100 starts at step 1102. At step 1104, the vehicle determines whether the ignition is on and whether a power reset occurred before or during a crank event. If it is determined at step 1104 that the ignition is on and power reset did not occur before or during the crank event, the vehicle determines, at step 1106, whether before the crank event the energy storage device showed a consistently low voltage or a consistently greater than a full charged voltage. If at step 1106, it is determined that the energy storage device did not consistently show a low voltage or a greater than a fully charged voltage, the vehicle may conclude that a normal engine crank event has occurred, at step 1114, and the process ends at step 1116.

If at step 1106, it is determined that the energy storage device either showed a persistently low voltage or persistently greater than a fully charged voltage value, the vehicle may conclude, at step 1108, that the energy storage device is not functioning optimally and that a low battery crank event has occurred. The vehicle may then send an alert notification indicating an issue with the energy storage device. If at step 1104, the vehicle determines that a power reset did occur before or during the crank event, the vehicle may further determine, at step 1110, whether the reset occurred in response to some sort of a diagnostic evaluation or whether a battery management system state of charge (BMS SOC) quality factor is within a threshold. The BMS SOC is a measure used to evaluate the accuracy and reliability of the SOC estimation provided by the BMS. The SOC Quality Factor is a performance metric that quantifies how well the SOC estimate corresponds to the actual charge level of the battery, taking into account potential errors or uncertainties in the estimation process. If at step 1110, it is determined that either the BMS SOC quality factor is within a threshold or the power reset was associated with a diagnostic reset, the vehicle may conclude that a normal crank even occurred, at step 1114.

If it is determined at step 1110 that either the power reset was not due to a diagnostic reset event or that the BMS SOC quality factor is outside of the threshold, the vehicle may determine, at step 1112, whether the vehicle moved a pre-determined number of times or whether the vehicle cranked satisfactorily for a predetermined number of times. If it is determined at step 1112 that the vehicle either did not move the predetermined number of times or did not crank satisfactorily for the predetermined number of times, the vehicle may conclude that energy storage device is not functioning properly and a less-than-optimal crank even occurred, at step 1108. If it is determined at step 1112, that the vehicle either moved the predetermined number of times or cranked satisfactorily for the predetermined number of times, the vehicle may conclude that a normal crank event occurred, at step 1114.

FIG. 12 depicts a block diagram of an example control server 1200 (e.g., control server 104 of FIG. 1) upon which any of one or more techniques (e.g., methods) may be performed or which may perform the methods described above in conjunction with the vehicle 102, in accordance with one or more example embodiments of the present disclosure. In other embodiments, the server 1200 may operate as a standalone device or may be connected (e.g., networked) to other servers. In a networked deployment, the server 1200 may operate in the capacity of a server machine, a client machine, or both in server-client network environments. In an example, the server 1200 may act as a peer server in peer-to-peer (P2P) (or other distributed) network environments. The server 1200 may be a personal computer (PC), a tablet PC, a set-top box (STB), a personal digital assistant (PDA), a mobile telephone, a smart key fob, a wearable computer device, a web appliance, a network router, a switch or bridge, or any machine capable of executing instructions (sequential or otherwise) that specify actions to be taken by that server, such as a base station. Further, while only a single server is illustrated, the term “server” shall also be taken to include any collection of servers that individually or jointly execute a set (or multiple sets) of instructions to perform any one or more of the methodologies discussed herein, such as cloud computing, software as a service (SaaS), or other computer cluster configurations.

Examples, as described herein, may include or may operate on logic or a number of components, modules, or mechanisms. Modules are tangible entities (e.g., hardware) capable of performing specified operations when operating. A module includes hardware. In an example, the hardware may be specifically configured to carry out a specific operation (e.g., hardwired). In another example, the hardware may include configurable execution units (e.g., transistors, circuits, etc.) and a computer-readable medium containing instructions where the instructions configure the execution units to carry out a specific task when in operation. The configuring may occur under the direction of the execution units or a loading mechanism. Accordingly, the execution units are communicatively coupled to the computer-readable medium when the device is operating. In this example, the execution units may be a member of more than one module. For example, under operation, the execution units may be configured by a first set of instructions to implement a first module at one point in time and reconfigured by a second set of instructions to implement a second module at a second point in time.

The server (e.g., computer system) 1200 may include a hardware processor 1202 (e.g., a central processing unit (CPU), a graphics processing unit (GPU), a hardware processor core, or any combination thereof), a main memory 1204 and a static memory 1206, some or all of which may communicate with each other via an interlink (e.g., bus) 1208. The server 1200 may further include a graphics display device 1210, an alphanumeric input device 1212 (e.g., a keyboard), and a user interface (UI) navigation device 1214 (e.g., a mouse). In an example, the graphics display device 1210, alphanumeric input device 1212, and UI navigation device 1214 may be a touch screen display. The server 1200 may additionally include a storage device (i.e., drive unit) 1216, a network interface device/transceiver 1220 coupled to antenna(s), and one or more sensors 1228, such as a global positioning system (GPS) sensor, a compass, an accelerometer, or another sensor. The server 1200 may include an output controller 1234, such as a serial (e.g., universal serial bus (USB)), parallel, or other wired or wireless (e.g., infrared (IR)), near field communication (NFC), etc. connection to communicate with or control one or more peripheral devices (e.g., a printer, a card reader, etc.).

The storage device 1216 may include a machine-readable medium 1222 on which is stored one or more sets of data structures or instructions (e.g., software) embodying or utilized by any one or more of the techniques or functions described herein. The instructions may also reside, completely or at least partially, within the main memory 1204, within the static memory 1206, or within the hardware processor 1202 during execution thereof by the server 1200. In an example, one or any combination of the hardware processor 1202, the main memory 1204, the static memory 1206, or the storage device 1216 may constitute machine-readable media.

While the machine-readable medium 1222 is illustrated as a single medium, the term “machine-readable medium” may include a single medium or multiple media (e.g., a centralized or distributed database and/or associated caches and servers) configured to store the one or more instructions.

Various embodiments may be implemented fully or partially in software and/or firmware. This software and/or firmware may take the form of instructions contained in or on a non-transitory computer-readable storage medium. Those instructions may then be read and executed by one or more processors to enable performance of the operations described herein. The instructions may be in any suitable form, such as but not limited to source code, compiled code, interpreted code, executable code, static code, dynamic code, and the like. Such a computer-readable medium may include any tangible non-transitory medium for storing information in a form readable by one or more computers, such as but not limited to read-only memory (ROM); random access memory (RAM); magnetic disk storage media; optical storage media; a flash memory, etc.

The term “machine-readable medium” may include any medium that is capable of storing, encoding, or carrying instructions for execution by the server 1200 and that causes the server 1200 to perform any one or more of the techniques of the present disclosure, or that is capable of storing, encoding, or carrying data structures used by or associated with such instructions. Non-limiting machine-readable medium examples may include solid-state memories and optical and magnetic media. In an example, a massed machine-readable medium includes a machine-readable medium with a plurality of particles having resting mass. Specific examples of massed machine-readable media may include non-volatile memory, such as semiconductor memory devices (e.g., electrically programmable read-only memory (EPROM), or electrically erasable programmable read-only memory (EEPROM)) and flash memory devices; magnetic disks, such as internal hard disks and removable disks; magneto-optical disks; and CD-ROM and DVD-ROM disks.

The instructions may further be transmitted or received over a communications network using a transmission medium via the network interface device/transceiver 1220 utilizing any one of a number of transfer protocols (e.g., frame relay, internet protocol (IP), transmission control protocol (TCP), user datagram protocol (UDP), hypertext transfer protocol (HTTP), etc.). Example communications networks may include a local area network (LAN), a wide area network (WAN), a packet data network (e.g., the Internet), mobile telephone networks (e.g., cellular networks), plain old telephone (POTS) networks, wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, and peer-to-peer (P2P) networks, among others. In an example, the network interface device/transceiver 1220 may include one or more physical jacks (e.g., Ethernet, coaxial, or phone jacks) or one or more antennas to connect to the communications network. In an example, the network interface device/transceiver 1220 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the server 1200 and includes digital or analog communications signals or other intangible media to facilitate communication of such software. The operations and processes described and shown above may be carried out or performed in any suitable order as desired in various implementations. Additionally, in certain implementations, at least a portion of the operations may be carried out in parallel. Furthermore, in certain implementations, less than or more than the operations described may be performed.

It is to be noted that the vehicle implements and/or performs operations, as described here in the present disclosure, in accordance with the owner manual and safety guidelines. In addition, any action taken by the vehicle owner/driver based on recommendations or notifications provided by the vehicle should comply with all the rules specific to the location and operation of the vehicle (e.g., Federal, state, country, city, etc.). The recommendations or notifications, as provided by the vehicle, should be treated as suggestions and only followed according to any rules specific to the location and operation of the vehicle. In the above disclosure, reference has been made to the accompanying drawings, which form a part hereof, which illustrate specific implementations in which the present disclosure may be practiced. It is understood that other implementations may be utilized, and structural changes may be made without departing from the scope of the present disclosure. References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a feature, structure, or characteristic is described in connection with an embodiment, one skilled in the art will recognize such feature, structure, or characteristic in connection with other embodiments whether or not explicitly described.

Further, where appropriate, the functions described herein can be performed in one or more hardware, software, firmware, digital components, or analog components. For example, one or more application-specific integrated circuits (ASICs) can be programmed to carry out one or more of the systems and procedures described herein. Certain terms are used throughout the description, and claims refer to particular system components. As one skilled in the art will appreciate, components may be referred to by different names. This document does not intend to distinguish between components that differ in name but not in function.

It should also be understood that the word “example,” as used herein, is intended to be non-exclusionary and non-limiting in nature. More particularly, the word “example,” as used herein, indicates one among several examples, and it should be understood that no undue emphasis or preference is being directed to the particular example being described.

A computer-readable medium (also referred to as a processor-readable medium) includes any non-transitory (e.g., tangible) medium that participates in providing data (e.g., instructions) that may be read by a computer (e.g., by a processor of a computer). Such a medium may take many forms, including, but not limited to, non-volatile media and volatile media. Computing devices may include computer-executable instructions, where the instructions may be executable by one or more computing devices, such as those listed above, and stored on a computer-readable medium.

With regard to the processes, systems, methods, heuristics, etc., described herein, it should be understood that, although the steps of such processes, etc., have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating various embodiments and should in no way be construed so as to limit the claims.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein and that the disclosed systems and methods will be incorporated into such future embodiments. In sum, it should be understood that the application is capable of modification and variation.

All terms used in the claims are intended to be given their ordinary meanings as understood by those knowledgeable in the technologies described herein unless an explicit indication to the contrary is made herein. In particular, use of singular articles such as “a,” “the,” “said,” etc. should be read to recite one or more of the indicated elements unless a claim recites an explicit limitation to the contrary. Conditional language, such as, among others, “can,” “could,” “might,” or “may,” unless specifically stated otherwise or otherwise understood within the context as used, is generally intended to convey that certain embodiments could include, while other embodiments may not include, certain features, elements, and/or steps. Thus, such conditional language is not generally intended to imply that features, elements, and/or steps are in any way required for one or more embodiments.

That which is claimed is:

1. A method comprising:
determining, by a vehicle, that an engine of the vehicle is running;
measuring, by the vehicle, a duty cycle signal associated with a voltage generator of the vehicle;
measuring, by the vehicle, a first voltage signal at a positive terminal of an energy storage device of the vehicle;
measuring, by the vehicle, a second voltage signal at an electronic control unit of the vehicle, the electronic control unit associated with a vehicle load;
determining, by the vehicle, that a first signal-to-noise ratio (SNR) associated with the duty cycle signal is below a first threshold;
determining, by the vehicle, a second SNR associated with the first voltage signal;
determining, by the vehicle, a third signal-to-noise SNR associated with the second voltage signal;
determining, by the vehicle, that each of the first, the second, and the third SNRs is lower than a respective threshold; and
determining, by the vehicle and based on the first, the second, and the third SNRs being below the respective thresholds, that the energy storage device is malfunctioning.

2. The method of claim 1, wherein the voltage generator comprises an alternator that includes a voltage regulator.

3. The method of claim 1, wherein the voltage generator comprises a belt-integrated starter generator.

4. The method of claim 1, wherein the first voltage signal is a B+ voltage signal associated with the energy storage device.

5. The method of claim 1, further comprising, generating, by the vehicle, a notification indicative of the energy storage device being defective.

6. The method of claim 1, wherein the energy storage device comprises a battery.

7. The method of claim 1, wherein the energy storage device comprises a bank of capacitors.

8. The method of claim 1, wherein each of the duty cycle signal, the first voltage signal, and the second voltage signal includes ripples.

9. A vehicle comprising:
an engine;
a voltage generator unit coupled to the engine;
an energy storage device coupled to the voltage generator unit;
a first electronic control unit (ECU) coupled to the energy storage device;
a second ECU coupled to a vehicle load; and
a memory unit storing instructions that when executed by the first ECU, cause the vehicle to:
determine that the engine is running;
measure a field duty cycle signal of the voltage generator unit;
measure, using the first ECU, a first voltage signal at a positive terminal of the energy storage device;
measure, using the second ECU, a second voltage signal at an input of the vehicle load;
determine that the field duty cycle signal, the first voltage signal, and the second voltage signal include ripples; and
determine, based on the field duty cycle signal, the first voltage signal, and the second voltage signal including ripples, that the energy storage device is defective.

10. The vehicle of claim 9, wherein the instructions further cause the vehicle to:
determine a first signal-to-noise ratio (SNR) associated with the first voltage signal;
determine a second SNR associated with the second voltage signal; and
determine that each of the first SNR and the second SNR is lower than a respective threshold.

11. The vehicle of claim 9, wherein the voltage generator unit is an alternator including a regulator.

12. The vehicle of claim 9, wherein the voltage generator unit is a belt-integrated starter generator.

13. The vehicle of claim 9, wherein the energy storage device comprises a 12V or a 48V battery.

14. The vehicle of claim 9, wherein the energy storage device comprises a bank of capacitors.

15. A method comprising:
measuring a first voltage signal associated with a first electronic control unit (ECU) of a vehicle;
measuring a second voltage signal associated with an energy storage device of the vehicle;
measuring a third voltage signal associated with a second ECU of the vehicle, the second ECU being different from the first ECU;
determining that a respective signal-to-noise ratio of each of the first voltage signal, the second voltage signal, and the third voltage signal is lower than a respective threshold; and
determining, based on a respective SNR of the first voltage signal, the second voltage signal, and the third voltage signal being lower than the respective thresholds, that the energy storage device is defective.

16. The method of claim 15, wherein the first ECU is associated with a body control module (BCM) of the vehicle.

17. The method of claim 15, further comprising outputting a notification indicating that the energy storage device is defective.

18. The method of claim 15, wherein the energy storage device includes a battery or a bank of capacitors.

19. The method of claim 15, wherein measuring the second voltage signal comprises measuring a B+ voltage associated with the energy storage device.

20. The method of claim 15, wherein the third voltage signal is associated with a load of the vehicle that is different than the energy storage device.
